(19) United States
(12) Patent Application Publication
(10) Pub. No.: US 2013/0298965 A1
(43) Pub. Date: Nov. 14, 2013

(54) SOLAR MODULE AND FABRICATING METHOD THEREOF

(71) Applicant: AU OPTRONICS CORPORATION, HSIN-CHU (TW)

(72) Inventors: John LIU, HSIN-CHU (TW); I-Min CHAN, HSIN-CHU (TW)

(73) Assignee: AU OPTRONICS CORPORATION, HSIN-CHU (TW)

(21) Appl. No.: 13/833,618

(22) Filed: Mar. 15, 2013

(30) Foreign Application Priority Data
May 14, 2012 (CN) 201210148958.6

(51) Int. Cl. H01L 31/052

(52) U.S. Cl. CPC H01L 31/0527
USPC 136/246

(57) ABSTRACT

A solar module is disclosed, which includes a back plate, a reflecting structure, one or more solar cell units, a bottom sealant, a top sealant, and a transparent plate. The reflecting structure is disposed on the back plate. The reflecting structure has inclines and a reflector layer. The solar cell units are disposed on the back plate. The solar cell units are spatially separated from and adjacent to the reflecting structure. The inclines are tilted towards nearby solar cell units. The reflector layer is disposed on the incline for directing the light toward the solar cell unit through total internal reflection. The bottom sealant is disposed between the back plate and the solar cell units. The top sealant is disposed on the solar cell units, and the transparent plate is disposed on the top sealant. A method for fabricating the solar module is also disclosed.

### RELATED APPLICATIONS

This application claims priority to China Application Serial Number 201210148958.6, filed May 14, 2012, which is herein incorporated by reference.

### BACKGROUND

1. Technical Field

The present invention relates to a solar module. More particularly, the present invention relates to a solar module with a reflecting structure.

2. Description of Related Art

In recent years, since the crude oil stock all around the world is decreased year by year, the energy source problem has become the focus of global attention. In order to solve the crisis of energy source depletion, the development and usage of various alternative energy sources become the urgent priority task. Since environmental awareness begins to prevail and the solar energy causes no pollution and is inexhaustible, the solar energy has become the biggest focus of attention in the relevant area. Therefore, in the position with sufficient sunshine, e.g., the buildings' roofs and squares, it becomes more and more common to see the installations of solar panels.

FIG. 1 is a top view of a conventional solar module. The solar module 10 mainly includes a back plate 11 and plural solar cell units 12 disposed on the back plate 11. For higher efficiency, mono-crystalline Si solar cell units 12 are often used. Mono-crystalline Si is grown in a round shape, though, and then cut, most commonly into the pseudo-square shape shown. In general, some gaps are preset among solar cell units 12 as the anticipation for assembling so as to prevent the solar cell units 12 from damage due to direct collision. However, these preset gaps may reduce the light utilization of the solar module 10. For example, the gaps between the sides of the solar cell units 12 occupy about 3% of the area of back plate 11, the gaps between the corners of the solar cell units 12 occupy about 2-3% of the area of back plate 11, and the gap between the outer edges (i.e., the edges of the back plate 11) of the solar cell units 12 occupy about 3-4% of the area of the back plate 11. In other words, about 10% of the area of the solar module 10 cannot be used effectively.

In general, through the usage of a white back plate by a solar module, about 30% of the light irradiating outside the solar cell unit can be reused. However even so, 70% of the light irradiating outside the solar cell unit still cannot be used effectively. Therefore, the power generation efficiency of the solar module is affected.

### SUMMARY

Therefore, the present invention provides a solar module with a reflecting structure for improving the light utilization of the solar module.

According to an aspect of the present invention, a solar module is provided, including a back plate, a bottom sealant disposed on the back plate, plural solar cell units disposed on the bottom sealant, a reflecting structure disposed on at least one side of the solar cell unit, a top sealant disposed on the solar cell unit and the reflecting structure, and a transparent plate. The reflecting structure includes a resin member and a reflector layer. The resin member includes inclines tilted towards nearby solar cell units and a connecting surface for connecting the inclines. The reflector layer is disposed on the incline for directing the light toward the solar cell unit.

Another aspect of the present invention provides a solar module, including a back plate, a solar cell unit, a bottom sealant, a top sealant, and a transparent plate. The back plate includes plural reflecting structures. Each of the reflecting structures has an incline, a connecting surface for connecting the incline, and a reflector layer. The solar cell unit is disposed on the back plate and located on at least one side of the reflecting structure. The inclines are each tilted towards a nearby solar cell unit. The reflector layer is disposed on the inclines. The bottom sealant is disposed between the back plate and the solar cell units. The top sealant is disposed on the solar cell unit. The transparent plate is disposed on the top sealant.

A further aspect of the present invention provides a method for fabricating a solar module. The method includes providing a back plate, providing a bottom sealant arranged on the back plate, arranging a reflecting structure on the bottom sealant, arranging solar cell units on the bottom sealant, in which the reflecting structures are disposed on at least one side of the solar cell units, arranging the top sealant on the solar cell units and the reflecting structures, arranging a transparent plate on the top sealant, and heating and laminating the back plate, the bottom sealant, the solar cell units, the reflecting structure, the top sealant and the transparent plate. Each of the reflecting structures includes a resin member and a reflector layer. The resin member includes inclines tilted towards nearby solar cell units and a connecting surface for connecting the inclines. The reflector layer is disposed on the inclines.

By using the reflecting structure disposed on one side of the solar cell units, light can be directed toward the solar cell units through reflection. According to the simulation results, about 65% of the light directly irradiating on the original gap can be reused. This improves the light utilization and the generating efficiency of the solar cell units.

### BRIEF DESCRIPTION OF THE DRAWINGS

In order to make the foregoing as well as other aspects, features, advantages, and embodiments of the present invention more apparent, the accompanying drawings are described as follows:

FIG. 1 is a top view of a conventional solar module;

FIG. 2 is a top view of an embodiment of the solar module of the present invention;

FIG. 3 is a partial cross-sectional view of the solar module of the present invention along a line segment A-A of FIG. 2;

FIG. 4 is a partial cross-sectional view of the solar module of the present invention along a line segment B-B of FIG. 2;

FIG. 5A is a partial enlarged view of the solar module of FIG. 2;

FIG. 5B is a partial cross-sectional view of the solar module along the line segment C-C of FIG. 2;

FIG. 6 is a flow chart of an embodiment of a method for fabricating a solar module of the present invention;

FIG. 7 is a partial cross-sectional view of another embodiment of the solar module of the present invention, and the section line is at the same position as the line segment A-A of FIG. 2;

FIG. 8 is a partial cross-sectional view of a further embodiment of the solar module of the present invention, and the section line is at the same position as the line segment B-B of FIG. 2;

FIG. 9 is a partial cross-sectional view of yet a further embodiment of the solar module of the present invention, and the section line is at the same position as the line segment C-C of FIG. 2;

FIG. 10 is a partial cross-sectional view of still yet a further embodiment of the solar module of the present invention;

FIG. 11 is a partial cross-sectional view of an embodiment of the solar module of the present invention;

FIG. 12 is a partial cross-sectional view of another embodiment of the solar module of the present invention;

FIG. 13 is a partial cross-sectional view of a further embodiment of the solar module of the present invention; and

FIG. 14 is a partial cross-sectional view of yet a further embodiment of the solar module of the present invention.

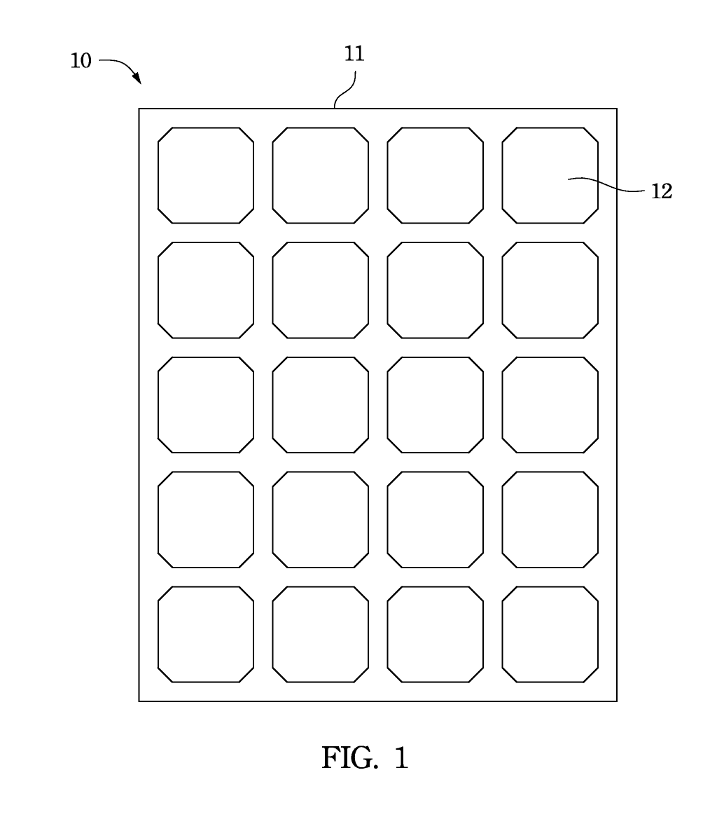

### DETAILED DESCRIPTION

The present invention is specifically described in the following examples. An example used at any position throughout the specification, including the usage of the examples using any terms discussed herein, is only used for illustration. Of cause, the example is not used for limiting the scope and meaning of the present invention or any terms in the examples. For those skilled in the art, various modification and variations can be made without departing from the spirit and scope of the present invention. Therefore, the scope of the present invention shall be defined by the appended claims. Additionally, the embodiments of the present invention may achieve plural technical effects, or the claims don't have to achieve all the aspects, advantages or features disclosed in the present invention. Those skilled in the art shall know that the embodiments and the elements thereof also include the inherent aspects, advantages or features that are not described expressly in the specification in addition to the aspects, advantages or features described in the specification. Therefore the description of the aspects, advantages or features throughout the specification is not intended to limit those skilled in the art in implementing the overall specification. Moreover, the abstract and title are used only for auxiliary searching of patent documents, without limiting the scope of the claims of the present invention.

Throughout the specification and the claims, the meaning of the articles “a”, “an” and “the” includes the description including “one or at least one” elements or components, unless specially noted. That is, singular articles also include the description of a plurality of elements or components, unless plurality is excluded obviously from the specific context. Furthermore, throughout the specification and the claims, “therein” may include the meaning of “therein” and “thereon”, unless specially noted. The meanings of “element A is on or under element B” and “element A is above or below element B” or other similar expressions of positional relations only indicate a relative position relation of the two elements, unless specially noted. Therefore, the direct or indirect couple of the two elements shall be included. Terms used throughout the specification and the claims typically have common meanings for each of the terms used in this field, in the present invention and in special contents, unless specially noted. Some terms for describing the present invention will be discussed in the following or elsewhere in this specification for providing practitioners with additional guidance related to the description of the present invention. Furthermore, it should be understood that the terms, “comprising”, “including”, “having”, “containing”, “involving” and the like, used herein are open-ended (i.e., including but not limited to).

The terms “substantially”, “around”, “about” or “approximately” shall generally mean that the error is within 20% of a specified value or range, and preferably within 10%. The number provided herein is proximate, so that it means that unless expressed specially, terms “around”, “about” or “approximately” can be used to modify the number.

With respect to the disclosure of the numerical value ranges, when the number, concentration or other numerical values or parameters have specified ranges, preferred ranges or tables listing upper and lower desired values, it should be considered that all the ranges formed by any of pair numbers with upper and lower limits or desired values are disclosed specially, no matter whether these ranges are disclosed independently or not. For example, if the length H of an element is disclosed in a range from X centimeters to Y centimeters, it should be considered that the length of the element is disclosed as H centimeters, and H may be selected as any real number from X to Y.

The spirit of the present invention will be illustrated clearly in the following detailed description with reference to the drawings. Those skilled in the art can make modifications and variations without departing from the spirit and scope of the present invention according to the techniques taught in the present invention after understanding the embodiments of the present invention.

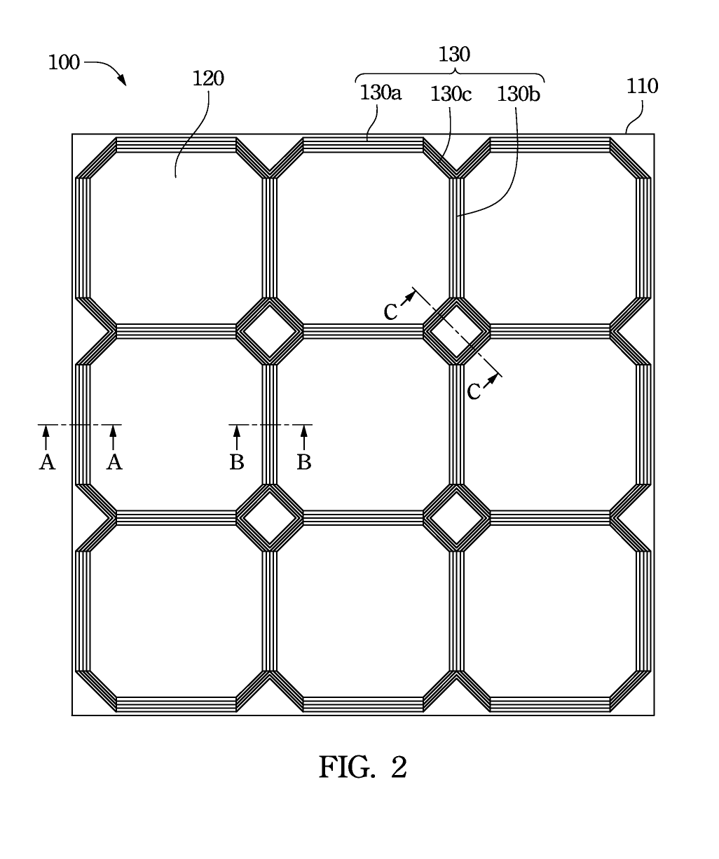

FIG. 2 is a top view of an embodiment of the solar module of the present invention. The solar module 100 includes a back plate 110 and solar cell units 120 disposed on the back plate 110. The solar module 100 further includes a reflecting structure 130 disposed on at least one side of the solar cell units 120 for directing the light irradiating on the reflecting structure 130 into the solar cell units 120 through one or more reflections to improve the light utilization. The reflecting structure 130 of this embodiment is an embeddable structure embedded in the back plate 110. According to different disposed positions, the reflecting structure 130 can be divided into an edge reflecting structure 130a disposed on the edge (located on the outer edge of the solar cell units 120) of the back plate 110, an side and side reflecting structure 130b disposed in the gap between the sides of the solar cell units, and a corner reflecting structure 130c disposed in the gap between the corner of the solar cell units 120. The distribution area of the solar cell units 120 occupies at least 80% of the area of the solar module 100.

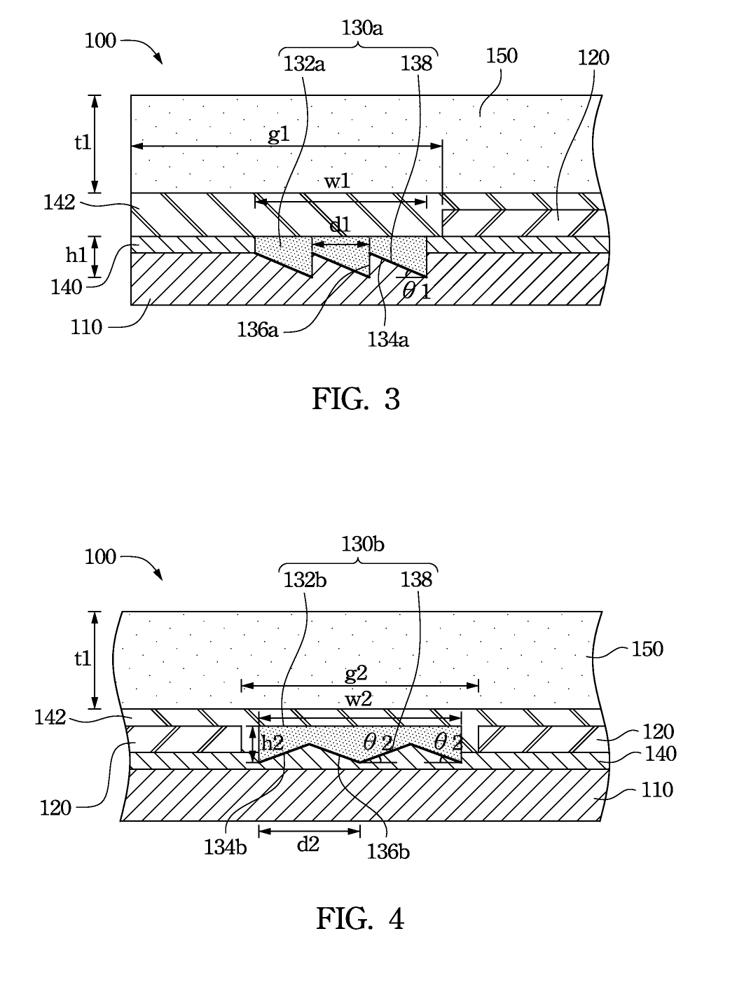

FIG. 3 is a partial cross-sectional view of the solar module of the present invention along the line segment A-A of FIG. 2. The solar module 100 includes a back plate 110, a bottom sealant 140 disposed on the back plate 110, solar cell units 120 disposed on the bottom sealant 140, an edge reflecting structure 130a disposed on one side of the solar cell units 120, a top sealant 142 and a transparent plate 150. The edge reflecting structure 130a includes a resin member 132a and a reflector layer 138. The resin member 132a includes a plurality of inclines 134a tilted towards nearby solar cell units 120 and plural connecting surfaces 136a for connecting the inclines 134a. The reflector layer 138 is disposed on the incline 134a and located between the back plate 110 and the incline 134a for directing the light irradiating on the incline 134a toward the solar cell unit 120 for use through one or more reflections. For example, the incline 134a directs the light irradiating on the incline 134a toward the solar cell unit 120 for use through total internal reflection. The connecting surface 136a may for example be perpendicular to the back plate 110 for increasing the distribution density of the incline 134a in per unit area. The included angle θ1 between the incline 134a and the back plate 110 is preferably in the range of 21 degrees to 45 degrees, and the included angle between the connecting surface 136a and the back plate 110 may for example be larger than the included angle θ1 between the incline 134a and the back plate 110 or may be approximately perpendicular to the back plate 110 as described above. The included angle θ1 between the incline 134a of the edge reflecting structure 130a and the back plate 110 may be a fixed angle. The distribution width of the edge reflecting structure 130a is from 10 mm to 30 mm. When the distribution width w1 of the edge reflecting structure 130a is larger than twice of the thickness t1 of the transparent plate 120, the included angle θ1 is 21−47.6*(r−0.5) degrees, wherein r is the ratio of the thickness t1 of the transparent plate 120 to the width g1 of the gap. Alternatively, when the distribution width w1 of the edge reflecting structure 130a is smaller than or equal to twice of the thickness t1 of the transparent plate 120, the included angle θ1 is 21 degrees.

The top sealant 140 and the bottom sealant 142 may be made of ethylene vinyl acetate resin (EVA), low density polyethylene (LDPE), high density polyethylene (HDPE), Silicone, Epoxy, Polyvinyl Butyral (PVB), Thermoplastic Polyurethane (TPU) or the combinations thereof. Furthermore, the materials of the top sealant 140 and the bottom sealant 142 are selected from (but not limited to) one of EVA, LDPE, HDPE, Silicone, Epoxy, PVB and TPU or the groups thereof.

The resin member 132a may be made of Polymethyl methacrylate (PMMA), Polyethylene terephthalate (PET), or Polymethyl methacrylimide (PMMI). Furthermore, the material of the resin member 132a is selected from one of PMMA, PET and PMMI or the combinations thereof. The back plate may be made of Polyvinyl Fluoride (PVF), Polyethylene terephthalate (PET), Polyethylene Naphthalate (PEN) or the combinations thereof. Furthermore, the material of the back plate is selected from one of PVF, PET and PEN or the combinations thereof. The bottom sealant 140 may be integrated in the back plate 110.

The edge reflecting structure 130a is not limited to be disposed on the same horizontal plane with the solar cell unit 120. For example, the shortest distance between the upper surface of the edge reflecting structure 130a facing the transparent plate 150 and the back plate 110 may be larger than, equal to or smaller than the shortest distance between the lower surface of the solar cell unit 120 facing the back plate 110 and the back plate 110. The resin member 132a may be located on the back plate 110, for example, directly arranged on the surface of the back plate 110. Alternatively, an accommodation groove is preprocessed on the back plate 110 to make part of or the entire resin member 132a be embedded into the back plate 110. For example, if the thickness t1 of the transparent plate 150 is 3.2 mm, the distribution width w1 of the edge reflecting structure 130a is about 10-20 mm; the height h1 of the edge reflecting structure 130a is about 200 μm; and the width d1 of each of the inclines 134a is about 261 μm. According to experiment data, about 65% of the light irradiating on the edge reflecting structure 130a can be directed toward the solar cell unit 120 through total internal reflection, for reusing by the solar cell unit 120.

The reflector layer 138 may be made of a metal with good reflectivity, e.g., silver, aluminum or an alloy thereof. The reflector layer 138 may be formed on the inclines 134a by using surface metallization, e.g., deposition or sputtering. The resin member 132a may be fabricated through imprinting, hot embossing or injection molding. The thickness of the reflector layer 138 is about 50 nm to 300 nm.

FIG. 4 is a partial cross-sectional view of the solar module of the present invention along the line segment B-B of FIG. 2. The solar module 100 includes a back plate 110, a bottom sealant 140 disposed on the back plate 110, a solar cell unit 120 disposed on the bottom sealant 140, a side and side reflecting structure 130b disposed in the gap between the sides of the solar cell unit 120, a top sealant 142 and a transparent plate 150. The side and side reflecting structure 130b includes a resin member 132b and a reflector layer 138. The resin member 132b includes a plurality of inclines 134b tilted towards the nearby solar cell unit 120 and plural connecting surfaces 136b for connecting the inclines 134b. The connecting surface 136b of the side and side reflecting structure 130b is an incline facing the solar cell unit 120 on the other side. The reflector layer 138 is disposed on the incline 134b and the connecting surface 136b for directing the light irradiating on the incline 134b and the connecting surface 136b toward the solar cell units 120 for use through one or more reflections. For example, the light on the incline 134b and the connecting surface 136b is directed toward the solar cell unit 120 for use through total internal reflection to increase the light utilization. The included angle θ2 between the incline 134b and the back plate 110 is preferably in the range of 21 degrees to 30 degrees. The included angle θ2 between the connecting surface 136b and the back plate 110 is preferably in the range of 21 degrees to 30 degrees. The incline 134b and the connecting surface 136b may be disposed symmetrically.

The side and side reflecting structure 130b is not limited to be disposed on the same horizontal plane with the solar cell unit 120. For example, the shortest distance between the upper surface of the side and side reflecting structure 130b facing the transparent plate 150 and the back plate 110 may be larger than, equal to or smaller than the shortest distance between the lower surface of the solar cell unit 120 facing the back plate 110 and the back plate 110. The resin member 132b may be located on the back plate 110, for example, directly arranged on the surface of the back plate 110. Alternatively, an accommodation groove is preprocessed on the back plate 110 to make part of or the entire resin member 132b be embedded in the back plate 110. The distribution width w2 of the side and side reflecting structure 130b is determined by the width g2 of the gap between the sides of two adjacent solar cell units 120. The distribution width w2 of the side and side reflecting structure 130b is slightly smaller than or equal to the width g2 of the gap between the sides of the solar cell unit 120. For example, the thickness t1 of the transparent plate 150 is 3.2 mm; the distribution width w2 of the side and side reflecting structure 130b is about 3 mm; the height h2 of the side and side reflecting structure 130b is about 200 μm; and the width d2 of each of the inclines 134b or the connecting surface 136b is about 520 μm.

The materials of the back plate 110, the top sealant 140, the bottom sealant 142, the resin member 132b and the reflector layer 138 as described above will not be described again. The methods for fabricating the resin member 132b and the reflector layer 138 are also described as above.

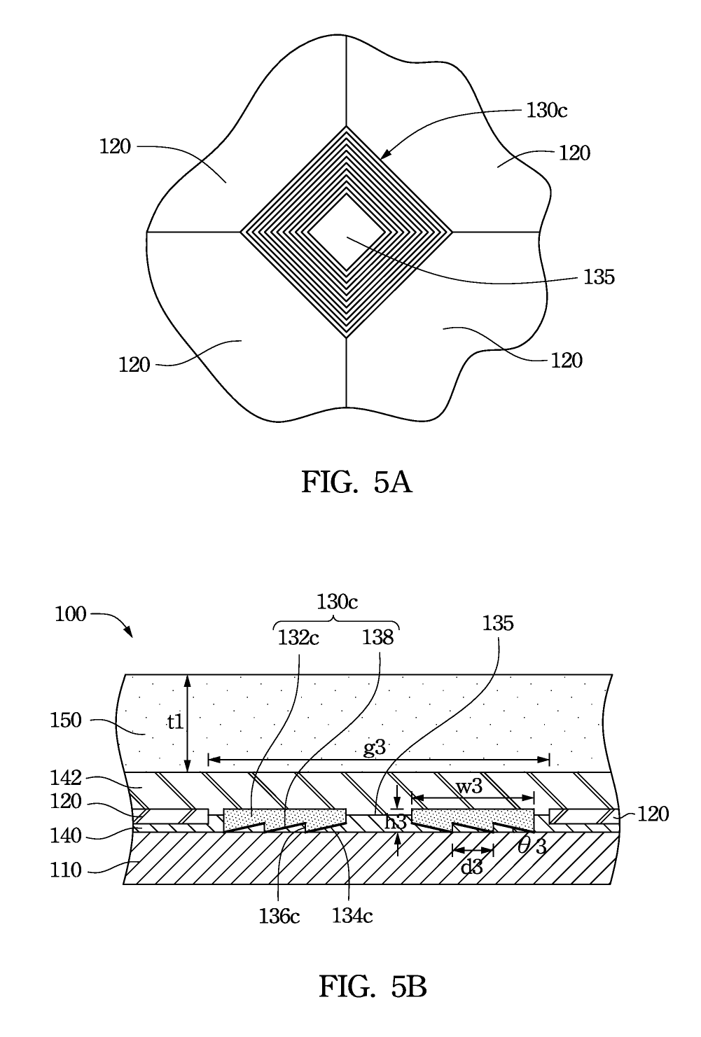

Please Refer both to FIG. 5A and FIG. 5B. FIG. 5A is a partial enlarged view of the solar module 100 of FIG. 2. FIG. 5B is a partial cross-sectional view of the solar module along the line segment C-C of FIG. 2. The solar module 100 includes a back plate 110, a bottom sealant 140 disposed on the back plate 110, a solar cell unit 120 disposed on the bottom sealant 140, a corner reflecting structure 130c disposed in the gap between the corners of the solar cell units 120, a top sealant 142 and a transparent plate 150.

The corner reflecting structure 130c is located in the gap between the corners of the solar cell unit 120, but is not limited to be disposed on the same horizontal plane with the solar cell unit 120. For example, the shortest distance between the upper surface of the corner reflecting structure 130c facing the transparent plate 150 and the back plate 110 may be larger than, equal to or smaller than the shortest distance between the lower surface of the solar cell unit 120 facing the back plate 110 and the back plate 110. More particularly, the gap may be formed between the corners of four solar cell units 120. The corner reflecting structure 130c is located in this gap. The corner reflecting structure 130c includes a resin member 132c and a reflector layer 138. The resin member 132c includes four sets of inclines 134c facing the nearest solar cell unit 120 and four sets of connecting surfaces 136c for connecting the inclines 134c. The corner reflecting structure 130c further includes an intermediate region 135. The inclines 134c surrounds the intermediate region 135. The intermediate region 135 surrounded by the incline 134c may be a physical structure such as a part of the resin member 132c, or the intermediate region 135 may be a non-physical cavity, an opening or a groove. The intermediate region 135 substantially has a plane. The incline 134c each faces the four solar cell units 120 surrounding the corner reflecting structure 130c. The reflector layer 138 is disposed on the incline 134c for directing the light irradiating on the incline 134c toward the solar cell unit 120 for use through one or more reflections. For example, the incline 134c directs the light irradiating on the incline 134c toward the solar cell unit 120 for use through total internal reflection to increase the light utilization. The connecting surface 136c is preferably perpendicular to the back plate 110 for increasing the distribution density of the incline 134c. The resin member 132c may be located on the back plate 110, for example, directly arranged on the surface of the back plate 110. Alternatively, an accommodation groove is preprocessed on the back plate 110 to make part of or the entire resin members 132c be embedded in the back plate 110.

The distribution width w3 (here it refers to the part facing a single solar cell unit 120) of the corner reflecting structure 130c is determined by the thickness t1 of the transparent plate 150 and the width g3 of the gap between the corners of the solar cell unit 120. For example, when the width g3 of the gap between the corners of the solar cell unit 120 is smaller than or equal to five times of the thickness t1 of the transparent plate 150, the distribution width w3 of the corner reflecting structure 130c is the smaller one of twice of the thickness t1 of the transparent plate 150 or half of the width g3 of the gap. When the width g3 of the gap between the corners of the solar cell units 120 is larger than five times of the thickness t1 of the transparent plate 150, the distribution width w3 of the corner reflecting structure 130c is 1.8(t1+0.15*g3). For example, if the thickness t1 of the transparent plate 150 is 3.2 mm and the width g3 of the gap between the corners is 22 mm, the distribution width w3 of the corner reflecting structure 130c is about 6.4 mm; the height h3 of the corner reflecting structure 130c is about 200 μm; and the width d3 of each of the inclines 134c is about 261 μm.

The materials of the back plate 110, the top sealant 140, the bottom sealant 142, the resin member 132c and the reflector layer 138 as described above will not be described again. The methods for fabricating the resin member 132c and the reflector layer 138 are also described as above.

The included angle θ3 between the incline 134c and the back plate 110 may be a fixed angle. The size of this included angle θ3 is also determined by the thickness t1 of the transparent plate 150 and the width g3 of the gap between the corners. When the width g3 of the gap between the corners of the solar cell unit 120 is smaller than or equal to the five times of the thickness t1 of the transparent plate 120, the included angle θ3 is preferably about 21 degrees. When the width g3 of the gap between the corners of the solar cell unit 120 is larger than five times of the thickness t1 of the transparent plate, the included angle θ3 is preferably 21−60*(r−0.2) degrees, wherein r is the ratio of the thickness t1 of the transparent plate 120 to the width g3 of the gap between corners.

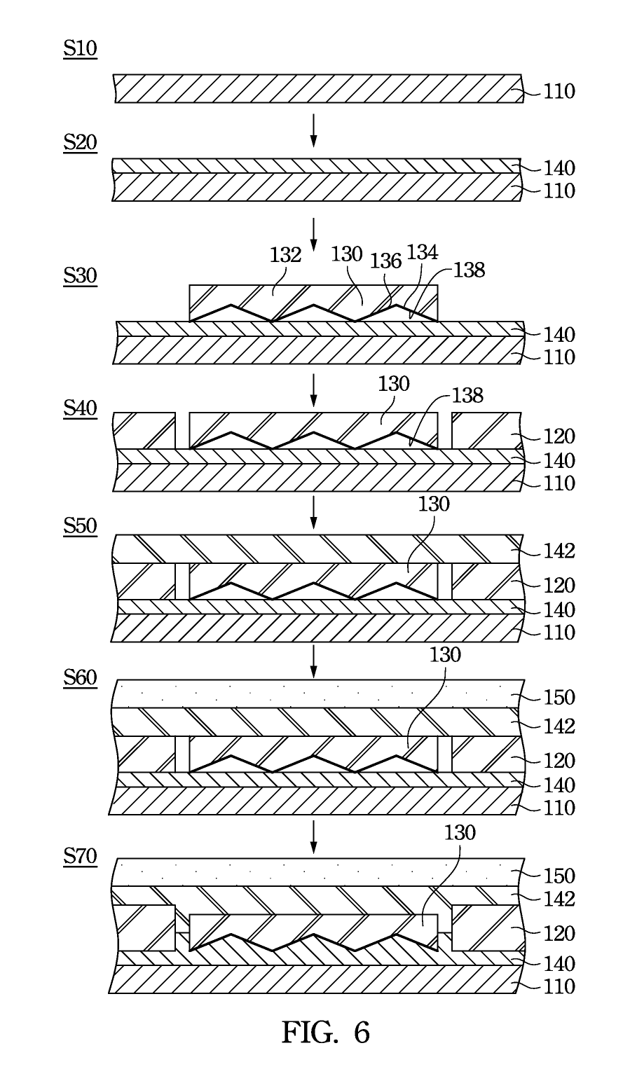

FIG. 6 is a flow chart of an embodiment of a method for fabricating a solar module of the present invention. In step S10, a back plate 110 is provided. The material of the back plate 110 includes PVF, PET, PEN or any combination thereof. The back plate 110 may have a smooth surface or an accommodation groove preformed thereon.

In step S20, a bottom sealant 140 is disposed on the back plate 110. The material of the bottom sealant 140 may be or may include (but not limited to) EVA, LDPE, HDPE, Silicone, Epoxy, PVB, TPU or the combinations thereof. The bottom sealant 140 may be integrated into the back plate 110.

In step S30, a reflecting structure 130 is arranged on the bottom sealant 140.

In step S40, the solar cell unit 120 is arranged on the bottom sealant 140. The reflecting structure 130 is disposed on at least one side of the solar cell unit 120. The reflecting structure 130 includes a resin member 132 and a reflector layer 138. The resin member 132 includes an incline 134 facing the solar cell unit 120 and a connecting surface 136 for connecting the incline 134. The reflector layer 138 is at least disposed on the incline 134. According to the different arranged positions, the reflecting structure 130 may be divided into an edge reflecting structure, a side and side reflecting structure and a corner reflecting structure. The specific structure has been illustrated as above. This figure illustrates a side and side reflecting structure. This embeddable reflecting structure 130 may be directly disposed on the bottom sealant 140. Alternatively, a corresponding accommodation groove is preprocessed on the back plate 110 for accommodating the reflecting structure 130. Because the reflector layer 138 of the reflecting structure 130 is disposed on one side facing the back plate 110, when an electrical connection is applied between the solar cell units 120, the contact of the reflector layer 138 to a solder strip will not cause a short circuit problem.

In step S50, the top sealant 142 is arranged on the solar cell unit 120 and a reflecting structure 130. The material of the top sealant 142 may be or may include (but not limited to) EVA, LDPE, HDPE, Silicone, Epoxy, PVB, TPU or the combinations thereof.

In step S60, a transparent plate 150 is arranged on a top sealant 142.

In step S70, the back plate 110, the bottom sealant 140, the solar cell unit 120, the reflecting structure 130, the top sealant 142 and the transparent plate 150 are heated and laminated for bonding the top sealant 142 and the bottom sealant 140 so as to fix the back plate 110, the solar cell unit 120, the reflecting structure 130 and the transparent plate 150.

In addition to being embedded in the back plate 110 through a resin member 132, the reflecting structure 130 may also be formed directly on the back plate 110. This will be illustrated in detail in the following embodiments.

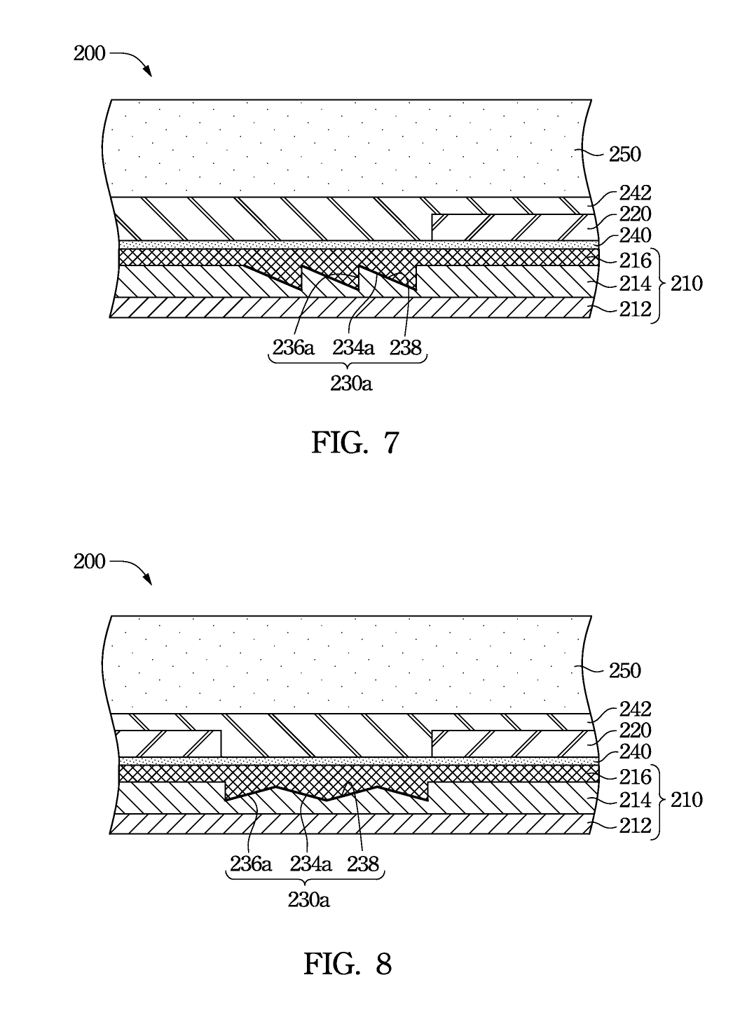

FIG. 7 is a partial cross-sectional view of another embodiment of the solar module of the present invention, and the section line is at the same position as the line segment A-A of FIG. 2. The solar module 200 includes a back plate 210, a bottom sealant 240 disposed on the back plate 210, a solar cell unit 220 disposed on the bottom sealant 240, a top sealant 242 and a transparent plate 250. The back plate 210 includes the lamination consisting of PVF layer 211, PET layer 214 and EVA layer 216. The bottom sealant 240 is disposed on the EVA layer 216.

A reflecting structure may be formed on the back plate 210 through imprinting, hot embossing or injection molding. The reflecting structure in this figure is an edge reflecting structure 230a disposed on the edge (the outer edge of the solar cell unit 220) of the back plate 210. The edge reflecting structure 230a may be formed on the PET layer 214. The edge reflecting structure 230a includes an incline 234a tilted towards the nearby solar cell unit 220 and a connecting surface 236a for connecting the incline 234a. The edge reflecting structure 230a further includes a reflector layer 238 disposed on the incline 234a for directing the light irradiating on the incline 234a toward the solar cell unit 220 for use through one or more reflections. For example, the incline 234a directs the light irradiating on the incline 234a toward the solar cell unit 220 for use through total internal reflection. The connecting surface 236a may be perpendicular to the back plate 220 for increasing the distribution density of the incline 234a in per unit area. The included angle between the incline 234a and the back plate 210 is preferably in the range of 21 degrees to 45 degrees. Specific rules may refer to the embodiments described above.

FIG. 8 is a partial cross-sectional view of a further embodiment of the solar module of the present invention, and the section line is at the same position as the line segment B-B of FIG. 2. The solar module 200 includes a back plate 210, a bottom sealant 240 disposed on the back plate 210, a solar cell unit 220 disposed on the bottom sealant 240, a top sealant 242 and a transparent plate 250. A side and side reflecting structure 230b is formed in the gap between the sides of the solar cell unit 220 by the back plate 210 through imprinting, hot embossing or injection molding. The side and side reflecting structure 230b may be formed on the PET layer 214.

The side and side reflecting structure 230b includes a plurality of inclines 234b facing the solar cell unit 220 and plural connecting surfaces 236b for connecting the incline 234b. The connecting surface 236b of the side and side reflecting structure 230b is an incline of the solar cell unit 220 facing the other side. The reflector layer 238 is disposed on the incline 234b and the connecting surface 236b for directing the light irradiating on the incline 234b and the connecting surface 236b toward the solar cell unit 220 for use through one or more reflections. For example, the incline 234b directs the light irradiating on the incline 234b toward the solar cell unit 220 for use through total internal reflection to increase the light utilization. The incline 234b and the connecting surface 236b may be disposed symmetrically.

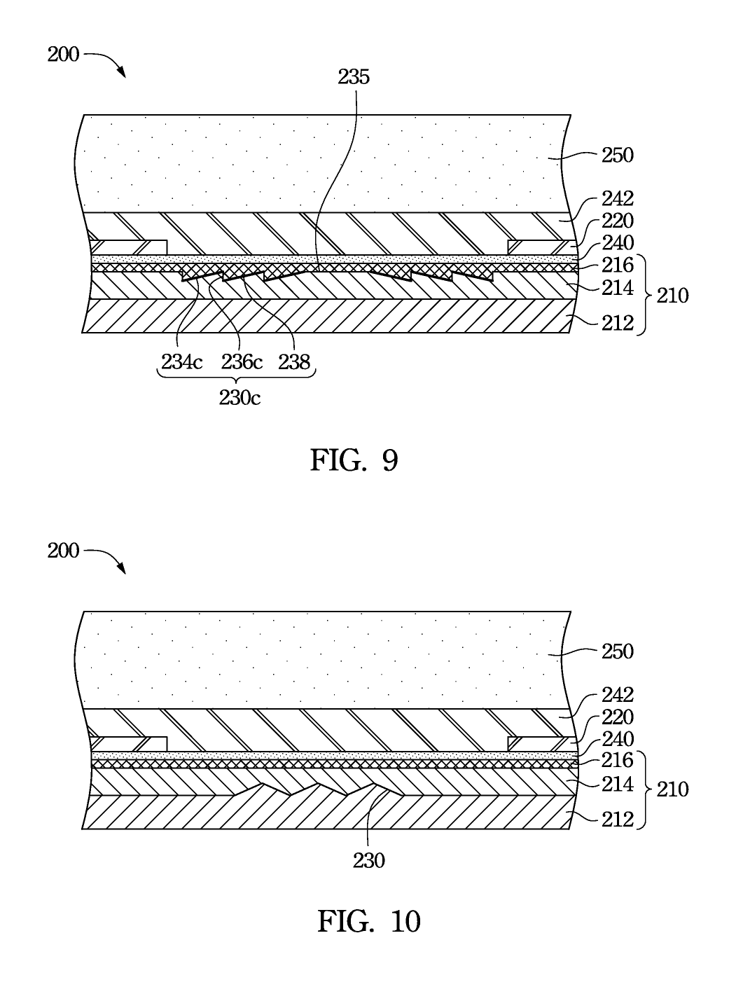

FIG. 9 is a partial cross-sectional view of yet a further embodiment of the solar module of the present invention, and the section line is at the same position as the line segment C-C of FIG. 2. The solar module 200 includes a back plate 210, a bottom sealant 240 disposed on the back plate 210, a solar cell unit 220 disposed on the bottom sealant 240, a top sealant 242 and a transparent plate 250. A corner reflecting structure 230c is formed and disposed in the gap between the corners of the solar cell units 220 by the back plate 210 through imprinting, hot embossing or injection molding. The corner reflecting structure 230c may be formed on the PET layer 214.

The corner reflecting structure 230c includes four sets of inclines 234c facing the solar cell units 220 and four sets of connecting surfaces 236c for connecting the inclines 234c. The corner reflecting structure 230c further includes an intermediate region 235. The incline 234c surrounds the intermediate region 235. The intermediate region 235 may be an opening, a plane or a groove for example. The inclines 234c face the four solar cell units 220 surrounding the corner reflecting structure 230c. The reflector layer 238 is disposed on the incline 234c for directing the light irradiating on the incline 234c toward the solar cell unit 220 for use through one or more reflections. For example, the incline 234c directs the light irradiating on the incline 234c toward the solar cell unit 220 for use through total internal reflection to increase the light utilization. The connecting surface 236c is preferably perpendicular to the back plate 210 for increasing the distribution density of the incline 234c.

FIG. 10 is a partial cross-sectional view of still yet a further embodiment of the solar module of the present invention. In this embodiment, the back plate 210 includes the lamination consisting of PVF layer 212, PET layer 214 and EVA layer 216. A recession (or an embossment) is formed on the PVF layer 212 by the reflecting structure 230 though imprinting, hot embossing or injection molding. After the face metallization of the reflecting structure 230, a PET layer 214 is distributed on the PVF layer 212. This embodiment aims at illustrating the change of the back plate 210. The reflecting structure 230 is not limited to the side and side reflecting structure illustrated in the figures. The reflecting structure 230 may also be an edge reflecting structure or a corner reflecting structure. Detailed description may refer to the embodiments described above.

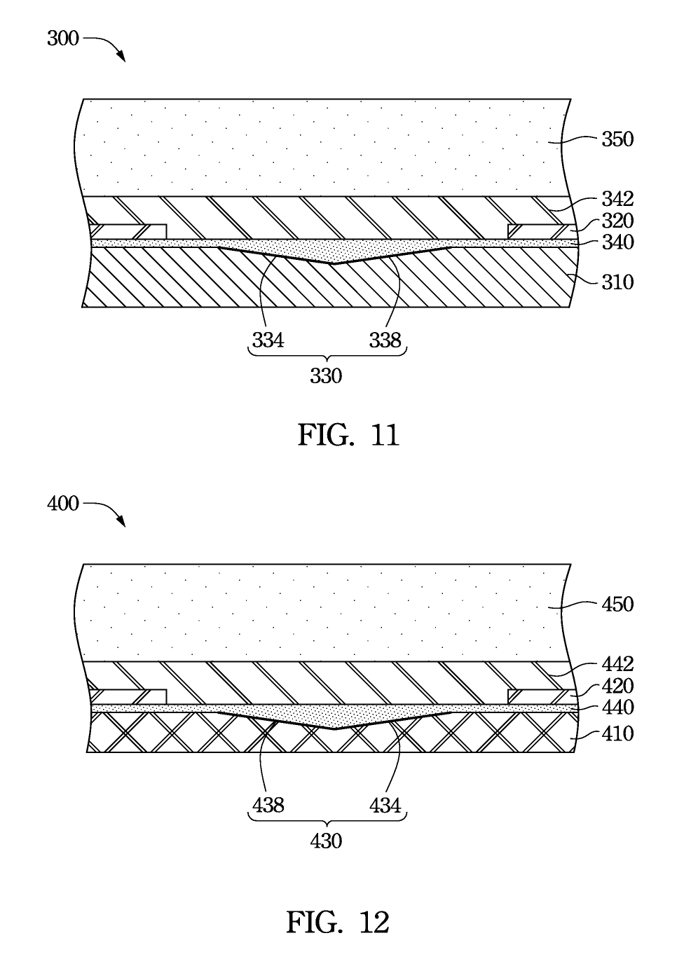

FIG. 11 is a partial cross-sectional view of an embodiment of the solar module of the present invention. The solar module 300 includes a back plate 310, a bottom sealant 340 disposed on the back plate 310, a solar cell unit 320 disposed on the bottom sealant 340, a top sealant 342 and a transparent plate 350. The back plate 310 and the transparent plate are glass plate. A reflecting structure 330 is formed on the back plate 310. Specifically, a recession (or an embossment) with an incline 334 is formed on the back plate 310. Then a reflector layer 338 is formed on the incline 334 through face metallization. This embodiment aims at illustrating the change of the back plate 310. The reflecting structure 330 is not limited to the side and side reflecting structure illustrated in the figures. The reflecting structure 230 may also be an edge reflecting structure or a corner reflecting structure. Detailed description may refer to the embodiments described above. The shortest distance between the upper surface of the reflecting structure 330 facing the transparent plate 350 and the back plate 310 may be larger than, equal to or smaller than the shortest distance between the lower surface of the solar cell unit 320 facing the back plate 310 and the back plate 310.

FIG. 12 is a partial cross-sectional view of another embodiment of the solar module of the present invention. The solar module 400 includes a back plate 410, a bottom sealant 440 disposed on the back plate 410, a solar cell unit 420 disposed on the bottom sealant 440, a top sealant 442 and a transparent plate 450. The back plate 410 may be a metal substrate. A reflecting 430 is formed on the back plate 410. Specifically, a recession (or an embossment) with an incline 434 is formed on the back plate 410. Then a reflector layer 438 is formed on the incline 434 through face metallization. This embodiment aims at illustrating the change of the back plate 410. The reflecting structure 430 is not limited to the side and side reflecting structure illustrated in the figures. The reflecting structure 430 may also be an edge reflecting structure or a corner reflecting structure. Detailed description may refer to the embodiments described above. The shortest distance between the upper surface of the reflecting structure 430 facing the transparent plate 450 and the back plate 410 may be larger than, equal to or smaller than the shortest distance between the lower surface of the solar cell unit 420 facing the back plate 410 and the back plate 410.

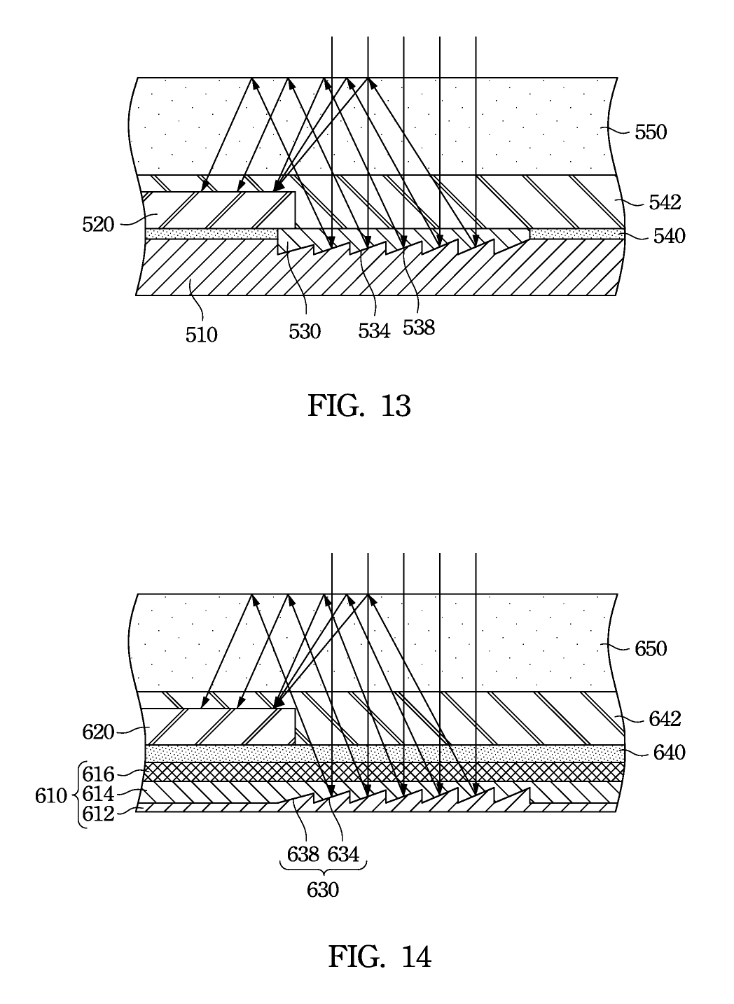

FIG. 13 is a partial cross-sectional view of a further embodiment of the solar module of the present invention. An embeddable reflecting structure 530 is employed in this embodiment. The reflecting structure 530 is disposed on the back plate 510. The solar cell unit 520 is located on one side of the reflecting structure 530. The solar cell unit 520 is respectively fixed to a back plate 510 and a transparent plate 550 by using a bottom sealant 540 and a top sealant 542. The reflecting structure 530 is not limited to be disposed on the same horizontal plane with the solar cell unit 520. For example, the shortest distance between the upper surface of the reflecting structure 530 facing the transparent plate 550 and the back plate 510 may be larger than, equal to or smaller than the shortest distance between the lower surface of the solar cell unit 520 facing the back plate 510 and the back plate 510.

The difference between this embodiment and the embodiments described above is that the included angle between the incline 534 of the reflecting structure 530 and the back plate 510 is a variable angle. The variable included angle is particularly adapted to the reflecting structure 530 with a wide bandwidth for example when the distribution width of the reflecting structure 530 is in the range of 20 mm to 50 mm. The included angle between the incline 534 and the back plate 510 progressively increases from the end close to the solar cell unit 520 to the other end far away from the solar cell unit 520. The included angle between the incline 534 and the back plate 510 at the end close to the solar cell unit 520 is 21 degrees. The included angle from the end of the reflecting structure 530 adjacent to the solar cell unit 520 is preferably 21 degrees in twice of the width of the transparent plate 550. The included angle increases progressively thereafter. The reflecting structure 530 with a variable angle may be applied to the edge reflecting structure shown in this figure. The reflecting structure 530 may also be applied to a corner reflecting structure or a side and side reflecting structure.

FIG. 14 is a partial cross-sectional view of yet a further embodiment of the solar module of the present invention. The difference between this embodiment and the embodiment described above is that a reflecting structure 630 is directly formed on a back plate 610. The back plate 610 includes the lamination consisting of PVF layer 612, PET layer 614, and EVA layer 616. The reflecting structure 630 is formed on the PVF layer 612. The solar cell unit 620 is located on one side of the reflecting structure 630. The solar cell unit 620 is respectively fixed to a back plate 610 and a transparent plate 650 by using a bottom sealant 640 and a top sealant 642. The included angle between the incline 634 of the reflecting structure 630 and the back plate 610 of this embodiment is a variable angle. The variable included angle is particularly adapted to the reflecting structure 630 with a wide bandwidth for example when the distribution width of the reflecting structure 630 is in the range of 20 mm to 50 mm.

The included angle between the incline 634 and the back plate 610 increases from the end close to the solar cell unit 620 to the other end far away from the solar cell unit 620 progressively. The included angle between the incline 634 and the back plate 610 at the end close to the solar cell unit 620 is 21 degrees. The included angle from the end of the reflecting structure 630 adjacent to the solar cell unit 620 is preferably 21 degrees in twice of the width of the transparent plate 650. The included angle increases thereafter progressively. The reflecting structure 630 with a variable angle may be applied to the edge reflecting structure shown in this figure. The reflecting structure 630 may also be applied to a corner reflecting structure or a side and side reflecting structure.

It can be seen from the preferred embodiments of the present invention, the application of the present invention has the following advantages. Using the reflecting structure disposed on one side of the solar cell unit, such as the reflecting structure disposed in the gap between the solar cell units (including the outer edge of the solar cell unit, the gaps between the sides of the solar cell unit and the angels of the solar cell unit), the light is directed toward the solar cell unit through one or more reflections, such as the total internal reflection. According to the measurement results, about 65% of the light directly irradiating on the original gap can be reused. This improves the light utilization and the generating efficiency of the solar cell units.

Although a preferred embodiment of the present invention has been disclosed with reference to the above embodiments, these embodiments are not intended to limit the present invention. It will be apparent to those skilled in the art that various modifications and variations may be made without departing from the spirit and scope of the present invention. Therefore, the scope of the present invention shall be defined by the appended claims.

What is claimed is:

1. A solar module, comprising:
a first substrate;
a first sealant disposed on the first substrate;
a plurality of solar cell units disposed on the first sealant;
a plurality of reflecting structures disposed on at least one side of the solar cell units, wherein each of the reflecting structures comprises:
a resin member including a plurality of inclines tilted towards the nearby solar cell units and a plurality of connecting surfaces for connecting the inclines; and
a plurality of reflector layers disposed between the inclines and the first substrate;
a second sealant disposed on the solar cell units and the reflecting structures; and
a transparent plate disposed on the second sealant.

2. The solar module of claim 1, wherein the material of the resin member is Polymethyl methacrylate (PMMA), Polyethylene terephthalate (PET) and Polymethyl methacrylimide (PMMI) or the combinations thereof.

3. The solar module of claim 1, wherein the material of the first substrate is Polyvinyl Fluoride (PVF), Polyethylene terephthalate (PET), Polyethylene Naphthalate (PEN) and ethylene vinyl acetate resin (EVA) or the combinations thereof.

4. The solar module of claim 1, wherein part of or the entire each of the resin members is embedded in the first substrate.

5. A solar module, comprising:
a first substrate comprising a plurality of reflecting structures, each of the reflecting structures having a plurality of inclines and a plurality of connecting surfaces for connecting the inclines;
a plurality of solar cell units located on at least one side of the reflecting structures, wherein the inclines are each tilted towards the nearby solar cell units;
a plurality of reflector layers disposed between the inclines and the first substrate;
a first sealant disposed between the first substrate and the solar cell units;
a second sealant disposed on the solar cell units; and
a transparent plate disposed on the second sealant.

6. The solar module of claim 5, wherein the material of the first substrate is PVF, PET, PEN, EVA, metal and glass or the combinations thereof.

7. The solar module of claim 5, wherein the reflecting structures comprise:
a plurality of first reflecting structures located in a gap formed by the edges of the first substrate and the solar cell units, wherein the inclines of the first reflecting structures are tilted towards the nearby solar cell units, and the connecting surfaces of the first reflecting structures face the edge of the first substrate.

8. The solar module of claim 7, wherein the distribution widths of the first reflecting structures are in the range of 10 mm to 30 mm.

9. The solar module of claim 8, wherein the distribution widths of the first reflecting structures are smaller than or equal to twice of the thickness of the transparent plates, the included angle is about 21 degrees.

10. The solar module of claim 8, wherein the distribution widths of the first reflecting structures are larger than twice of the thickness of the transparent plates, the included angle is about 21−47.6*(r−0.5) degrees, wherein r is the ratio of the thickness of the transparent plate to the width of the gap.

11. The solar module of claim 7, wherein the included angle between the inclines of the first reflecting structures and the first substrate is a variable angle, and the distribution widths of the first reflecting structures are in the range of 20 mm to 50 mm.

12. The solar module of claim 11, wherein the included angle between the inclines of the first reflecting structures and the first substrate increases from the end close to the solar cell unit to the other end progressively.

13. The solar module of claim 11, wherein the included angle between the inclines of the first reflecting structures and the first substrate near the solar cell units is about 21 degrees.

14. The solar module of claim 5, wherein the reflecting structures comprise:
a plurality of second reflecting structures, located in the gap between the sides of the solar cell units, wherein the inclines of the second reflecting structures face the solar cell unit located on one side of the second reflecting structure, the connecting surfaces of the second reflecting structures face the solar cell unit on the other side of the second reflecting structures, and the reflector layers are further disposed on the connecting surfaces.

15. The solar module of claim 5, wherein the reflecting structures comprise:
a plurality of third reflecting structures located in the gap between the corners of the solar cell units, wherein each of the third reflecting structures comprises the inclines, the connecting surfaces and an intermediate region, the inclines each face the four solar cell units holding the third reflecting structure, the inclines surround the intermediate region, and the intermediate region is a plane, a groove or an opening.

16. The solar module of claim 15, wherein when the widths of the gap between the corners of the solar cell units are smaller than or equal to five times of the thickness of the transparent plate, the distribution width of the third reflecting structures is the smaller one of twice of the thickness of the transparent plate or half of the width of the gap.

17. The solar module of claim 15, wherein when the width of the gap between the corners of the solar cell units is larger than or equal to the five times of the thickness of the transparent plate, the distribution width of the third reflecting structure is about 1.8*(t+0.15*g), wherein t is the thickness of the transparent plate and g is the width of the gap.

18. The solar module of claim 15, wherein the included angle between the inclines and the first substrate is a fixed angle, and when the width of the gap between the angles of the solar cell units is smaller than or equal to five times of the thickness of the transparent plate, the included angle is about 21 degrees.

19. The solar module of claim 15, wherein the included angle between the inclines and the first substrate is a fixed angle, and when the width of the gap between the angles of the solar cell units is larger than five times of the thickness of the transparent plate, the included angle is about 21−60*(r−0.2) degrees, wherein r is the ratio of the thickness of the transparent plate to the width of the gap.

20. The solar module of claim 5, wherein the first substrate comprises the lamination of PVF and PET, and the reflecting structure is formed on the PVF layer or the PET layer.

21. The solar module of claim 5, wherein the materials of the reflector layers are silver, aluminum or the alloy thereof, and the thickness of the reflector layers are about 50 nm to 300 nm.
